(19) United States
(12) Patent Application Publication
(10) Pub. No.: US 2018/0228043 A1
(43) Pub. Date: Aug. 9, 2018

(54) ELECTRONIC DEVICE

(71) Applicant: KYOCERA Corporation, Kyoto (JP)

(72) Inventor: Masaki MICHIWAKI, Yokohama-shi (JP)

(73) Assignee: KYOCERA Corporation, Kyoto (JP)

(21) Appl. No.: 15/889,435

(22) Filed: Feb. 6, 2018

Related U.S. Application Data
(60) Provisional application No. 62/456,872, filed on Feb. 9, 2017.

(30) Foreign Application Priority Data
Feb. 9, 2017 (JP) 2017-021859

(51) Int. Cl. H05K 5/03; H05K 5/00; G06F 1/16

(52) U.S. Cl. CPC H05K 5/03; H05K 5/0017; G06F 1/1656; G06F 3/041; G06F 1/1643; G06F 1/1601; H05K 5/0008

(57) ABSTRACT

An electronic device comprises a composite panel including a glass panel having a glass surface positioned on the front surface side and a scratch-resistant resin panel joined to the glass surface by a joining member. The electronic device comprises a housing supporting the glass panel. The housing comprises an outer peripheral portion that is positioned around the periphery of the glass surface and is not in contact with a surface of the scratch-resistant resin panel on the front surface side. In a state in which the scratch-resistant resin panel is joined to the glass panel, the outer peripheral portion projects further in a direction perpendicular to the scratch-resistant resin panel than the surface of the scratch-resistant resin panel on the front surface side.

### CROSS-REFERENCE TO RELATED APPLICATION

The present application claims priority to and the benefit of Japanese Patent Application No. 2017-021859 (filed on Feb. 9, 2017) and U.S. Provisional Application No. 62/456,872 filed Feb. 9, 2017, the entire contents of which are incorporated herein by reference.

### TECHNICAL FIELD

The present disclosure relates to an electronic device that includes a panel.

### BACKGROUND

Electronic devices which include a panel formed from glass or synthetic resin are known.

### SUMMARY

An electronic device according to an embodiment of the present disclosure comprises a composite panel. The composite panel includes a glass panel having a glass surface positioned on a front surface side and a scratch-resistant resin panel joined to the glass surface by a joining member. The electronic device comprises a housing supporting the glass panel. The housing comprises an outer peripheral portion that is positioned around the periphery of the glass surface and is not in contact with a surface of the scratch-resistant resin panel on the front surface side. In a state in which the scratch-resistant resin panel is joined to the glass panel, the outer peripheral portion projects further in a direction perpendicular to the scratch-resistant resin panel than the surface of the scratch-resistant resin panel on the front surface side.

### BRIEF DESCRIPTION OF THE DRAWINGS

In the accompanying drawings:

FIG. 1 is a plan view illustrating an example configuration of an electronic device according to an embodiment;

FIG. 2 is a cross-section view along the A-A line in FIG. 1;

FIG. 3 is an enlarged view of the portion of FIG. 2 encircled by a dashed line;

FIG. 4 is a cross-section view along the B-B line in FIG. 1 illustrating an example configuration of a front panel;

FIG. 5 illustrates an example configuration of a scratch-resistant resin panel;

FIG. 6 illustrates an example joining position of the scratch-resistant resin panel;

FIG. 7 illustrates a comparative example of the joining position of the scratch-resistant resin panel;

FIG. 8 illustrates an example of the positional relationship between the edge of the scratch-resistant resin panel and a pivot point;

FIG. 9 illustrates an example of access by a jig to the edge of the scratch-resistant resin panel; and

FIG. 10 is a cross-section illustrating an example configuration of a front panel according to another embodiment.

### DETAILED DESCRIPTION

A panel may be scratched or may crack due to an external impact or the like. It is desired to reduce the risk of scratching or cracking of the panel of an electronic device.

It would therefore be helpful to provide an electronic device which reduces the risk of the panel being scratched or cracked.

An electronic device according to the present embodiment may be a mobile electronic device such as a mobile phone or a smartphone. However, the electronic device according to the present embodiment is not limited to a mobile electronic device. The electronic device may be any of a variety of electronic devices, such as a desktop personal computer (PC), a notebook PC, a tablet PC, a household appliance, an industrial device or a factory automation (FA) device, or a dedicated terminal.

For example, the electronic device of a comparative example includes a panel formed from a synthetic resin. In contrast, the electronic device according to the present embodiment includes a composite panel in which glass and resin are joined at a glass surface. Unlike a panel formed only from resin, this composite panel in which glass and resin are joined at the glass surface can present the user with the texture of a glass panel. Thus, the electronic device according to the present embodiment can present a user that touches the panel with the texture of a glass panel while reducing the risk of cracking that is normally associated with a panel that includes glass.

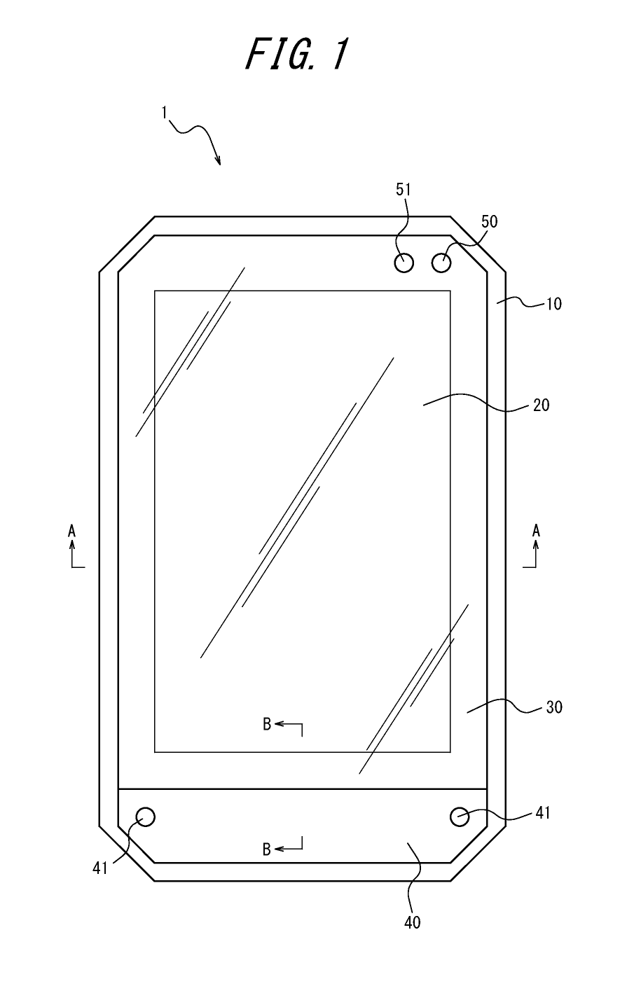

As illustrated in FIG. 1, the electronic device 1 according to an embodiment includes a housing 10, a display 20, a composite panel 30, and a front panel 40. The electronic device 1 may further include a front camera 50 or an illumination sensor 51. The face of the electronic device 1 where the display 20 and the composite panel 30 are positioned is also referred to as the front face. The composite panel 30 has a first surface oriented towards the front face of the electronic device 1 and a second surface oriented towards the opposite side from the first surface. The second surface can also be considered to be oriented towards the interior side of the electronic device 1. The first surface and the second surface are also referred to as the front surface and the back surface when viewing the electronic device 1 from the front face thereof.

As illustrated in FIG. 2, the composite panel 30 includes a glass panel 31 and a scratch-resistant resin panel 32. The scratch-resistant resin panel 32 is joined to the glass panel 31 to be positioned on the first surface side with respect to the glass panel 31. The glass panel 31 is joined to the housing 10 at edges thereof on the second surface side. The display 20 is joined to the second surface side of the glass panel 31. An internal structure 60 is provided in the area enclosed by the housing 10 and the composite panel 30. The internal structure 60 may be a battery, for example, or may be a substrate that includes a processor, an electronic circuit, or the like functioning as a controller for controlling the components of the electronic device 1. The internal structure 60 may include the front camera 50 or the illumination sensor 51.

The controller of the electronic device 1 is, for example, configured by a processor. The controller may include one or more processors. The term “processor” encompasses universal processors that execute particular functions by reading particular programs and dedicated processors that are specialized for particular processing. Dedicated processors include integrated circuits (ICs) for specific purposes, also referred to as application specific integrated circuits (ASICs). The processor may include a programmable logic device (PLD). The PLD may include a field-programmable gate array (FPGA). The controller may be either a system-on-a-chip (SoC) or a system in a package (SiP) with one processor or a plurality of processors that work together.

The display 20 displays characters, images, objects for operation, pointers, and the like on the basis of information acquired from the controller or the like of the electronic device 1. Non-limiting examples of the display 20 include display devices such as a liquid crystal display, an organic electroluminescence (EL) display, or an inorganic EL display.

The glass panel 31 may include a touch sensor. When the glass panel 31 includes a touch sensor, the glass panel 31 may also be referred to as a touch panel. The touch panel detects touch input by the user. When a touch panel is joined to the display 20, the display 20 may also be referred to as a touch panel display.

The front camera 50 captures images of subjects positioned on the front face side of the electronic device 1. The front camera 50 may include an image sensor. The front camera 50 may include an optical system such as a lens. The illumination sensor 51 detects the degree of illumination at the front face side of the electronic device 1. The electronic device 1 may control the luminance of images displayed on the display 20 in accordance with the degree of illumination.

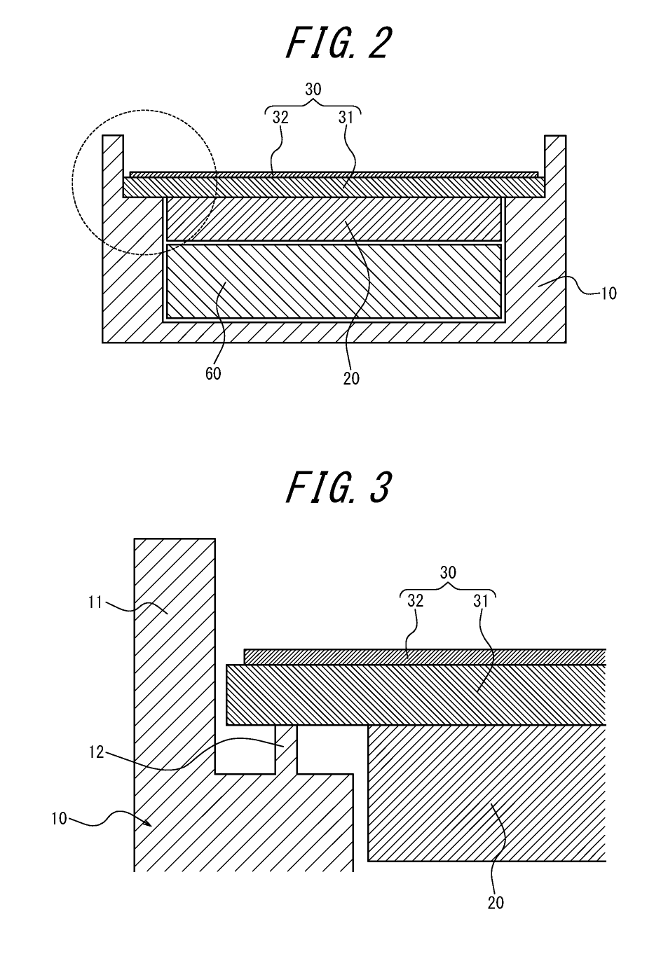

As illustrated in FIG. 3, the housing 10 includes an outer peripheral portion 11 and a support 12. The outer peripheral portion 11 is also referred to as a rim. The housing 10 may, for example, be formed from a material such as a metal or a resin. The housing 10 may be configured by a composite material of metal, resin, or the like. The housing 10 may be configured by a variety of other materials.

The composite panel 30 is disposed on the inside of the outer peripheral portion 11. The composite panel 30 is joined to the housing 10 so that the edge of the glass panel 31 is supported by the support 12 on the second surface side. In this case, the scratch-resistant resin panel 32 is oriented towards the front face of the electronic device 1. The display 20 is joined to the glass panel 31 on the second surface side. In other words, the display 20 is joined on the interior side of the housing 10. The display 20 can be considered to be joined to the housing 10 via the composite panel 30.

By virtue of the scratch-resistant resin panel 32 being oriented towards the front face of the electronic device 1, the glass panel 31 tends not to be scratched even when the electronic device 1 suffers an impact. The glass panel 31 is thus less prone to cracking. The scratch-resistant resin panel 32 may include a window, at a position corresponding to the front camera 50 or the illumination sensor 51, to allow incident light to pass through.

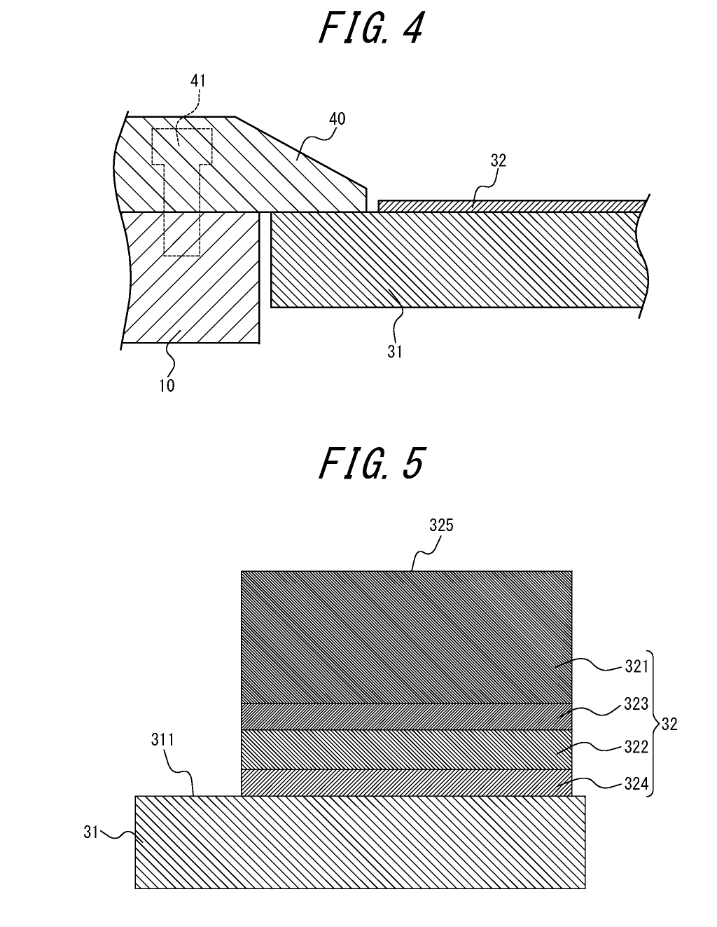

As illustrated in FIG. 4, the front panel 40 is arranged detachably on the front face side of the electronic device 1 so as to cover the edge of the glass panel 31 on the first surface side. This configuration can soften the impact to the edge of the glass panel 31. The glass panel 31 is thus less prone to damage. The front panel 40 is positioned so as to expose the edge of the scratch-resistant resin panel 32. With this approach, the front panel 40 is positioned alongside the scratch-resistant resin panel 32 at the front face of the electronic device 1. This configuration can reduce the thickness of the electronic device 1 as compared to when the front panel 40 is positioned to overlap the scratch-resistant resin panel 32.

The front panel 40 is joined to the housing 10 by a front panel joining portion 41. The front panel 40 may be configured to be detachable from the housing 10. The front panel joining portion 41 may, for example, be configured by a joining member such as a screw. The front panel 40 may be configured so that upon removal of the front panel 40 from the housing 10, a jig 33 for peeling off the scratch-resistant resin panel 32 (see FIG. 9) is insertable at the interface where the glass panel 31 and the scratch-resistant resin panel 32 are joined. In other words, the electronic device 1 may be configured to allow access, upon removal of the front panel 40 from the housing 10, to the interface where the glass panel 31 and the scratch-resistant resin panel 32 are joined.

As illustrated in FIG. 5, the scratch-resistant resin panel 32 includes a front surface portion 321 and a base material 322. The front surface portion 321 is positioned at the front face side of the electronic device 1 and is directly touched by the user's finger or the like. The front surface portion 321 may be a material with a relatively high hardness. The front surface portion 321 may be a material with abrasion resistance against the touch of a finger or the like. The front surface portion 321 may be a material that is not scratched easily upon colliding with objects or the like. The front surface portion 321 may be a material that is not easily penetrated by a colliding object. The front surface portion 321 may have a predetermined thickness. The predetermined thickness may be determined in accordance with the material so as to prevent penetration by a colliding object. The front surface portion 321 may, for example, be an acrylic resin. The front surface portion 321 is not limited to an acrylic resin and may, for example, be an organic resin.

The scratch-resistant resin panel 32 includes a first adhesive material 323 between the front surface portion 321 and the base material 322. The front surface portion 321 and the base material 322 are joined by the first adhesive material 323. The first adhesive material 323 may be a material with a high bonding strength with respect to the front surface portion 321. When the front surface portion 321 is an acrylic resin, the first adhesive material 323 may be an acrylic adhesive material or the like. When the front surface portion 321 is an organic resin, the first adhesive material 323 may be an organic adhesive material or the like.

The scratch-resistant resin panel 32 includes a second adhesive material 324 on the second surface side of the base material 322. The scratch-resistant resin panel 32 is joined to a glass surface 311 of the glass panel 31 by the second adhesive material 324. The glass surface 311 is assumed to be the surface of the glass panel 31 at the first surface side. The second adhesive material 324 may be a material with a high bonding strength with respect to the glass surface 311. The second adhesive material 324 may be a silicon adhesive material or the like.

The base material 322 may be a material with a high bonding strength with respect to both the first adhesive material 323 and the second adhesive material 324. When the first adhesive material 323 and the second adhesive material 324 are respectively an acrylic adhesive material and a silicon adhesive material, the base material 322 may, for example, be formed from polyethylene terephthalate (PET).

The front surface portion 321 includes a stain-resistant layer 325 on the first surface side corresponding to the front face side of the electronic device 1. The stain-resistant layer 325 makes it less likely that an oil component, for example from a fingerprint due to the user's touch, will stick to the composite panel 30. The composite panel 30 can thus be made less prone to accumulating dirt. The stain-resistant layer 325 may be a layer such as fluorine coating formed by any of various types of surface treatment.

Unlike a panel formed only from glass, the composite panel 30 includes the scratch-resistant resin panel 32, making the glass panel 31 less prone to being scratched. The panel can thus be made less prone to cracking. By including the stain-resistant layer 325 on the front face side of the electronic device 1, the composite panel 30 can also be made less prone to accumulating dirt. The glass surface 311 of the composite panel 30 is covered by the scratch-resistant resin panel 32 and therefore is free from risk of being soiled, unlike a panel formed only from glass. The glass surface 311 need not have a stain-resistant coating, such as a fluorine coating, applied thereon. The bonding strength between the glass panel 31 and the scratch-resistant resin panel 32 can be increased by joining the scratch-resistant resin panel 32 directly to the glass surface 311.

For example, in a device such as a smartphone including a panel formed only from glass, a stain-resistant coating is sometimes applied to the front surface of the panel. The user can use the device after adhering a protective sheet to the panel that has the stain-resistant coating. A stain-resistant coating is treatment to reduce the likelihood of dirt or the like adhering to the panel. The adhesive strength of the protective sheet to a panel with a stain-resistant coating may be lower than the adhesive strength to a panel without a stain-resistant coating.

The adhesive strength can be measured as the force necessary to peel apart two sheets, which are adhered to each other, at a constant speed. The glass panel 31 and the protective sheet may respectively be considered a rigid material and a flexible material. When measuring the adhesive strength between a rigid material and a flexible material, the sheet may be peeled by 180 degree peeling. 180 degree peeling is a method whereby a flexible material is peeled from a rigid material by bending the flexible material at an angle near to 180 degrees. Actual measurement indicated that the adhesive strength between a protective sheet and a glass panel 31 with a stain-resistant coating was 1/10 or less of the adhesive strength between a protective sheet and a glass panel 31 without a stain-resistant coating. In other words, the stain-resistant coating reduced the adhesive strength of the protective sheet. A different peeling method may be used to measure the adhesive strength, such as a T-peel method.

A protective sheet adhered to the glass panel 31 that has a stain-resistant coating might easily be peeled off, during normal use of the electronic device 1, by a fingernail or the like catching on the edge of the protective sheet. A protective sheet adhered to the glass panel 31 that has a stain-resistant coating might also easily be peeled off as a result of the adhesive strength being reduced due to oil, moisture, or the like penetrating through the adhesive interface between the protective sheet and the glass panel 31. A protective sheet adhered to the glass panel 31 that has a stain-resistant coating might also easily be peeled off if the protective sheet warps from the effect of heat or humidity, since the adhesive strength may not withstand the deformation. In contrast, in the composite panel 30 according to the present embodiment, the scratch-resistant resin panel 32 is joined to the glass surface 311 of the glass panel 31, which does not have a stain-resistant coating. With this configuration, the scratch-resistant resin panel 32 is less prone to peeling off than in the case of the user adhering a protective sheet.

The scratch-resistant resin panel 32 makes the glass panel 31 less prone to scratches. In return for the glass panel 31 being less prone to scratches, the scratch-resistant resin panel 32 may be scratched. The composite panel 30 is configured so that the glass panel 31 and the scratch-resistant resin panel 32, while being less prone to peeling, can still be peeled apart. By configuring the scratch-resistant resin panel 32 to be peelable, the scratch-resistant resin panel 32 alone can be replaced upon being scratched. In this case, the glass panel 31 need not be replaced. Repairs can thus be made easier.

The glass panel 31 may have a curved shape in a region near the edges of the housing 10. The scratch-resistant resin panel 32 that is joined to a curved glass panel 31 may be more prone to peeling at the edge where the curvature is large. When having a relatively low flexibility, the scratch-resistant resin panel 32 is more prone to peeling from the curved glass panel 31. When a stain-resistant coating is applied to the glass panel 31, the scratch-resistant resin panel 32 is more prone to peeling from the glass panel 31. By being joined to the glass surface 311 of the glass panel 31 that does not have a stain-resistant coating, the scratch-resistant resin panel 32 is not prone to peeling from the curved glass panel 31, even when the scratch-resistant resin panel 32 has a relatively low flexibility.

The texture that a user feels when touching a panel configured only from resin may differ from the texture the user feels when touching a glass panel. The composite panel 30 according to the present embodiment can present the texture of a glass panel while reducing the risk of cracking that is normally associated with a panel that includes glass.

The second adhesive material 324 may be configured so that when the scratch-resistant resin panel 32 is joined to the glass surface 311, air bubbles are less prone to remaining in the joining portion. For example, by appropriately setting the ratio between a weak adhesive component and a strong adhesive component, the second adhesive material 324 may be configured so that air bubbles can easily escape from the joining portion.

The glass panel 31 and the display 20 may be joined by a photocurable material that hardens upon being irradiated with ultraviolet light or the like. When the glass panel 31 and the display 20 are joined by a material that hardens upon being irradiated with UV light, the scratch-resistant resin panel 32 may be joined to the glass panel 31 after the glass panel 31 and the display 20 are joined. With this approach, the scratch-resistant resin panel 32 is not irradiated by UV light or the like. As a result, the properties of the scratch-resistant resin panel 32 can be prevented from changing due to irradiation by UV light or the like. When the scratch-resistant resin panel 32 is an acrylic resin, joining the glass panel 31 and the display 20 by irradiation with UV light or the like after the scratch-resistant resin panel 32 has been joined to the glass panel 31 may result in light with a wavelength in the UV region being absorbed by the acrylic resin. The amount of light necessary for hardening the photocurable material might therefore not be obtained. In contrast, joining the scratch-resistant resin panel 32 to the glass panel 31 after the glass panel 31 and the display 20 are joined can prevent this situation.

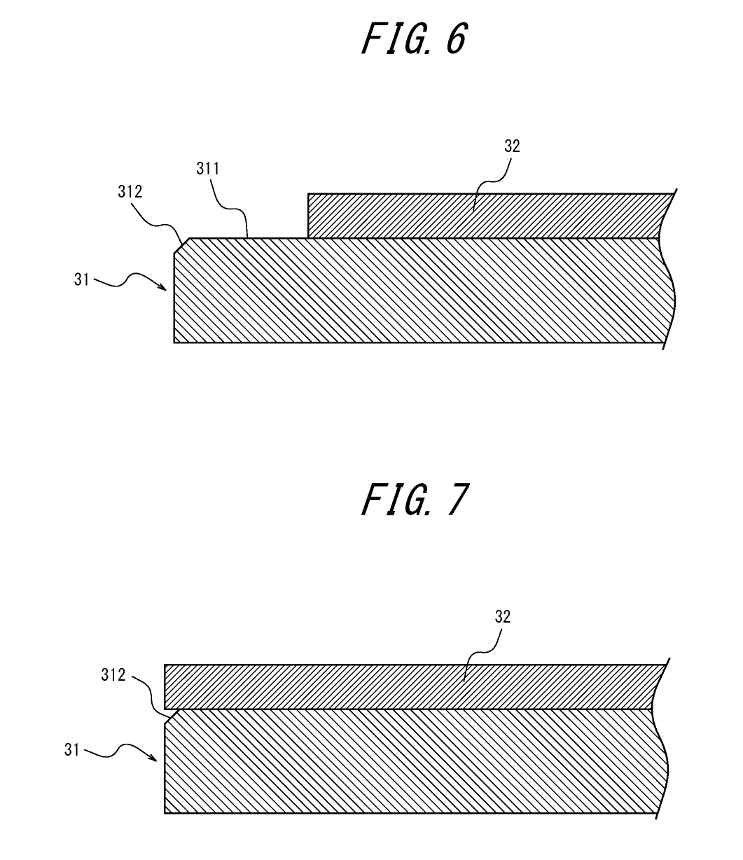

As illustrated in FIG. 6, the glass panel 31 may include a chamfered portion 312 at the edge of the glass surface 311. The chamfered portion 312 is positioned at the ridge between the glass surface 311 and the side face of the glass panel 31. The chamfered portion 312 is not limited to the example of 45 degree chamfering illustrated in FIG. 6 and may be a different chamfered shape, such as rounding. When the glass panel 31 includes the chamfered portion 312, the scratch-resistant resin panel 32 is joined to the glass panel 31 further inward than the chamfered portion 312. In other words, the edge of the scratch-resistant resin panel 32 is positioned at least a predetermined distance from the chamfered portion 312.

As illustrated in FIG. 7, when the edge of the scratch-resistant resin panel 32 is positioned to overlap the chamfered portion 312, a portion of the second adhesive material 324 of the scratch-resistant resin panel 32 is exposed. The bonding strength at the interface between the glass panel 31 and the scratch-resistant resin panel 32 may be reduced by dirt or the like adhering to the second adhesive material 324. The quality of appearance may also deteriorate if dirt or the like adheres to the second adhesive material 324. The composite panel 30 according to the present embodiment illustrated in FIG. 6 maintains the bonding strength between the glass panel 31 and the scratch-resistant resin panel 32 more easily than the configuration illustrated in FIG. 7. The composite panel 30 according to the present embodiment illustrated in FIG. 6 also maintains the quality of appearance more easily than does the configuration illustrated in FIG. 7.

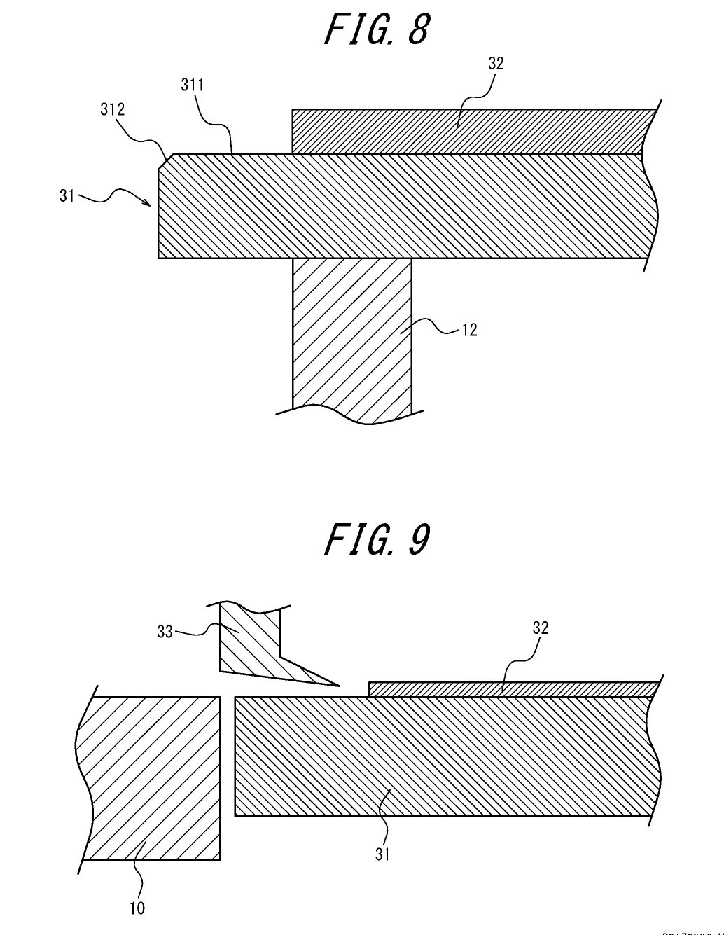

As illustrated in FIG. 8, the scratch-resistant resin panel 32 may overlap the position at which the glass panel 31 is supported by the support 12. The position at which the glass panel 31 is supported by the support 12 is also referred to as the pivot point. In other words, the edge of the scratch-resistant resin panel 32 may be positioned closer to the outer peripheral portion 11 of the housing 10 than the pivot point is. A relatively large stress is applied to the glass panel 31 at the pivot point. By the scratch-resistant resin panel 32 overlapping the pivot point, the stress on the composite panel 30 at the pivot point may also be distributed to the scratch-resistant resin panel 32. As a result, the stress on the composite panel 30 at the pivot point can be mitigated.

The scratch-resistant resin panel 32 may be damaged depending on the usage state of the electronic device 1. However, even if the scratch-resistant resin panel 32 is damaged, the impact can be absorbed by the scratch-resistant resin panel 32, thereby preventing the glass panel 31 from cracking. The scratch-resistant resin panel 32 may be replaced when damaged. Configuring the scratch-resistant resin panel 32 to be peelable from the glass panel 31 allows replacement of the scratch-resistant resin panel 32.

As illustrated in FIG. 9, once the front panel 40 is removed, the jig 33 can easily be inserted at the joining portion between the glass panel 31 and the scratch-resistant resin panel 32. The scratch-resistant resin panel 32 can be peeled off by inserting the jig 33 at the joining portion between the glass panel 31 and the scratch-resistant resin panel 32. In other words, the composite panel 30 is configured so that once the front panel 40 has been removed, the joining portion between the glass panel 31 and the scratch-resistant resin panel 32 is accessible by the jig 33.

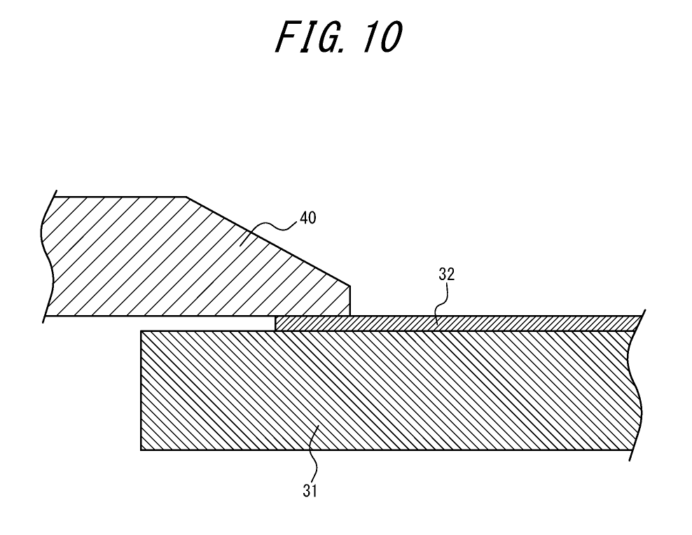

In the electronic device 1 according to another embodiment, the front panel 40 may cover the edge of the scratch-resistant resin panel 32, as illustrated in FIG. 10. In other words, while the front panel 40 is attached, the joining portion between the glass panel 31 and the scratch-resistant resin panel 32 is not exposed. Once the front panel 40 is removed, the joining portion between the glass panel 31 and the scratch-resistant resin panel 32 is exposed. Dirt is less likely to adhere to the edge of the scratch-resistant resin panel 32, and objects are less likely to collide with this configuration. As a result, the scratch-resistant resin panel 32 does not peel from the glass panel 31, unless being peeled intentionally.

The electronic device 1 according to an embodiment can reduce the risk of the panel being scratched or cracked.

Although an embodiment of the present disclosure has been described through drawings and examples, it is to be noted that various changes and modifications will be apparent to those skilled in the art based on the present disclosure. Therefore, such changes and modifications are to be understood as included within the scope of the present disclosure. For example, the functions or the like included in the various components may be reordered in any logically consistent way. Furthermore, components may be combined into one or divided. Such embodiments are also to be understood as encompassed within the scope of the present disclosure.

The references to “first”, “second”, and the like in the present disclosure are identifiers for distinguishing between elements. The numbers of elements distinguished by references to “first”, “second”, and the like in the present disclosure may be switched. For example, the identifiers “first” and “second” of the first adhesive material and the second adhesive material may be switched. Identifiers are switched simultaneously, and elements are still distinguished between after identifiers are switched. The identifiers may be removed. Elements from which the identifiers are removed are distinguished by their reference sign. Identifiers in the present disclosure, such as “first” and “second”, may not be used in isolation as an interpretation of the order of elements or as the basis for the existence of the identifier with a lower number.

1. An electronic device comprising:
a composite panel comprising a glass panel having a glass surface positioned on a front surface side and a scratch-resistant resin panel joined to the glass surface by a joining member; and
a housing supporting the glass panel, wherein
the housing comprises an outer peripheral portion that is positioned around the periphery of the glass surface and is not in contact with a surface of the scratch-resistant resin panel on the front surface side, and
in a state in which the scratch-resistant resin panel is joined to the glass panel, the outer peripheral portion projects further in a direction perpendicular to the scratch-resistant resin panel than the surface of the scratch-resistant resin panel on the front surface side.

2. The electronic device of claim 1, wherein a distance between an edge of the scratch-resistant resin panel and the outer peripheral portion in a surface direction of the glass surface is less than a distance by which the outer peripheral portion projects from an exposed surface of the scratch-resistant resin panel in the direction perpendicular to the scratch-resistant resin panel.

3. The electronic device of claim 1, wherein an edge of the scratch-resistant resin panel is exposed to the outside of the electronic device to allow replacement of the scratch-resistant resin panel.

4. The electronic device of claim 2, wherein the edge of the scratch-resistant resin panel is exposed to the outside of the electronic device to allow replacement of the scratch-resistant resin panel.
